(19) United States
(12) Patent Application Publication
(10) Pub. No.: US 2013/0092211 A1
(43) Pub. Date: Apr. 18, 2013

(54) ASYMMETRIC MIM TYPE ABSORBENT NANOMETRIC STRUCTURE AND METHOD FOR PRODUCING SUCH A STRUCTURE

(71) Applicants: Stéphane Collin, Paris (FR); Jean-Luc Pelouard, Paris (FR); Fabrice Pardo, Vitry-sur-Seine (FR); Philippe Lalanne, Palaiseau (FR); Christophe Sauvan, Meudon (FR); Anne-Marie Haghiri-Gosnet, Sceaux (FR)

(72) Inventors: Stéphane Collin, Paris (FR); Jean-Luc Pelouard, Paris (FR); Fabrice Pardo, Vitry-sur-Seine (FR); Philippe Lalanne, Palaiseau (FR); Christophe Sauvan, Meudon (FR); Anne-Marie Haghiri-Gosnet, Sceaux (FR)

(73) Assignee: CENTRE NATIONAL DE LA RECHERCHE SCIENTIFIQUE- CNRS, Paris (FR)

(21) Appl. No.: 13/642,953

(22) PCT Filed: Apr. 15, 2011
(86) PCT No.: PCT/EP2011/056028

§ 371 Date: Jan. 4, 2013

(30) Foreign Application Priority Data
Apr. 23, 2010 (FR) 1053134

(51) Int. Cl. H01L 31/052; H01L 31/18

(52) U.S. Cl. CPC H01L 31/0527; H01L 31/18; B82Y 99/00
USPC 136/246; 438/72; 977/948

(57) ABSTRACT

According to one aspect, the invention relates to an asymmetric MIM type absorbent nanometric structure (1, 1′) intended to receive a wide-band incident light wave the absorption of which is to be optimised within a given spectral band, comprising an absorbent dielectric layer (10) in said spectral band, of subwavelength thickness, arranged between a metal array (11) of subwavelength period and a metal reflector (12). The elements (110, 120) forming the metal array exhibit at least one dimension (w) suitable for forming a plasmonic resonator between the metal array and the metal reflector, under the elements of the array, which plasmonic resonator forms a Fabry-Pérot type longitudinal cavity resonating at a first wavelength of the aimed-for spectral absorption band, and the absorber layer exhibits, between the metal array and the metal reflector, at least one first thickness (tₐ) suitable for forming at least one first Fabry-Pérot type vertical cavity, resonating at a second wavelength of the aimed-for absorption spectral band.

### PRIOR ART

1. Technical Field of the Invention

The present invention relates to an asymmetric MIM type absorbent nanometric structure exhibiting wide-band light absorption, particularly in the visible range, and a method for producing such a structure. More particularly, it is applicable to ultra-thin solar cells.

2. Prior Art

Attempts are constantly being made to reduce the thickness of the active (absorber) layer of solar cells, or photovoltaic cells, in particular to reduce the transit time (time taken by electrons to reach the electrodes, which is generally more than a picosecond) and thus the recombining of photo-induced charges. Attempts are also being made to decrease the thickness of the active layer in order to reduce the costs associated with the material, both the cost of the material itself and the manufacturing cost incurred by processing a greater or smaller quantity of material. Furthermore, limiting the quantity of material enables greater scope for plans to use rare materials. In seeking to reduce the thickness of the active layer, one of the difficulties encountered is in producing a structure in which light can be confined within the active layer long enough (typically it is intended that the photon travels along an optical path several times greater than the thickness of the absorbing material) to enable maximum conversion efficiency. One method for confining electromagnetic waves (solar light) within the active layer is to attempt to excite surface plasmon resonances in structures on a subwavelength scale.

The article by Atwater et al. (‘Plasmonics for improved photovoltaic devices’, Nature Materials, 9, 205-213 (2010)) suggests integrating recent techniques implemented in the production of photovoltaic devices involving ‘plasmonics’. The purpose of plasmonics is to benefit from the resonant interaction between electromagnetic radiation (especially light) and free electrons at the interface between a metal and a dielectric material (such as air or glass) under certain conditions. This interaction generates electron density waves, exhibiting wave-like behaviour and called plasmons or surface plasmons. The article describes various types of metal nanostructures which enable the generation of surface plasmons, with the aim of trapping light in very thin semi-conductor layers, causing a large increase in absorption. In particular, the article describes the use of nanometric particles used as diffusing elements to promote coupling, the use of nanometric particles as nano-antennae, the use of a striated mirror behind a semi-conductor layer enabling the generation of surface plasmons at the mirror-semi-conductor interface.

Among the references cited by Atwater et al., for example the article by Ferry et al. (‘Improved red-response in thin film a-Si : H solar cells with soft-imprinted plasmonic black reflectors’, Appl. Phys. Letters 95, 183503 (2009)), describing the structuring of materials for solar-cell type applications, is particularly noteworthy. A structured metal layer on the back of the absorber layer enhances the absorption of longer wavelengths. However, in this article, the wide band absorption is obtained using a relatively thick active layer (500 nm) In Linguist et al. (‘Plasmonic nanocavity arrays for enhanced efficiency in organic photovoltaic cells’, Appl. Phys. Letters 93, 123308 (2008)), an array of nanocavities is formed between a structured metal anode and a (non-structured) cathode. This plasmonic structure enables the confinement of electromagnetic energy and an increase in the absorption of wavelengths greater than 700 nm, due to the existence of surface plasmons between the structured anode and the cathode.

Le Perchec at al. (‘Plasmon-based photosensors comprising a very thin semiconducting region’, Appl. Phys. Letters 94, 181104 (2009)) describes an infrared detection system comprising a very thin active layer. As in the solar cell applications, the mechanism for confining the light in the semi-conductor layer relies on the generation of plasmon resonances in a horizontal cavity formed by an MSM (metal-semi-conductor-metal) type structure in which the semi-conductor layer is sandwiched between a metal mirror underneath and a metal array on a subwavelength scale on top. It is shown that such a plasmon resonance can be modelled by a longitudinal Fabry-Pérot type resonator which verifies the relationship kn_{eff}L=π where k is the wave vector (k=2 π/λ where λ is the wavelength of the incident wave), n_{eff} is the effective index of the guided plasmon mode in the MSM multi-layer structure, L is the width of an element of the array.

These plasmon resonances shown in the articles cited above are generated at wavelengths greater than 650-700 nm. This is explained by the very nature of the surface plasmon at the metal-dielectric interface which cannot exist at short wavelengths (for example, see A. V. Zayats et al., ‘Nano-optics of surface plasmon polaritons’, Physics reports 408, 131-314, 2005).

Therefore, there is a necessity to produce ultra-thin structures exhibiting an increased wide band absorption in the visible range 500-800 nm.

The invention introduces an asymmetric MIM (metal-insulator-metal) type absorbent nanometric structure, the particular geometry of which enables in particular the generation of an increased absorption at wavelengths over the entire visible spectrum.

### SUMMARY OF THE INVENTION

According to a first aspect, the invention relates to an asymmetric MIM type absorbent nanometric structure intended for receiving a wide-band incident light wave the absorption of which is to be optimised within a given spectral band in the near-infrared visible range, characterised in that it comprises an absorbent dielectric layer in said spectral band, of subwavelength thickness, arranged between a metal array formed from metal elements periodically arranged with a subwavelength period and a metal reflector, and in that:

the elements forming the metal array exhibit at least one dimension (w) suitable for forming a plasmonic resonator between the metal array and the metal reflector, under the elements of the array, which plasmonic resonator forms a Fabry-Pérot type longitudinal cavity resonating at a first wavelength of the aimed-for absorption spectral band,

the absorber layer exhibits, between the metal array and the metal reflector, at least one first thickness suitable for forming at least one first Fabry-Pérot type vertical cavity, resonating at a second wavelength of the aimed-for absorption spectral band.

According to a variant embodiment, said at least first thickness of the absorber layer is less than the absorption length of the dielectric material of which said absorber layer is made on the aimed-for absorption spectral band.

According to a variant embodiment, said at least first thickness of the absorber layer is between subtantially once and two times the thickness of the metal skin forming the metal array.

According to a variant embodiment, the absorber layer exhibits a first thickness under the elements of the array and a second thickness under the spaces between the elements of the array, which thicknesses are suitable for forming a first and a second Fabry-Pérot type vertical cavity resonating at two distinct wavelengths of the aimed-for absorption spectral band.

According to a variant embodiment, the first and second thicknesses are substantially identical.

According to a variant embodiment, the width of the elements of the metal array is suitable for obtaining a plasmon mode of the order m=3.

According to a variant embodiment, the structure further comprises a non-absorbing dielectric layer in the aimed-for absorption spectral band, arranged between said absorber layers and the metal array and/or encapsulating the metal array, enabling the thickness between the metal array and the metal reflector to be adjusted.

According to a variant embodiment, the period of the metal array is less than half the minimum wavelength of the aimed-for absorption spectral band.

According to a variant embodiment, the metal array is one-dimensional, of a period between 150 and 250 nm and formed from strips with a width between 80 and 120 nm and a thickness between 10 and 30 nm.

According to a variant embodiment, the metal array is two-dimensional, of a period according to one or other of the dimensions between 150 and 250 nm, and is formed from square or rectangular pads of sides between 80 and 120 nm, and thickness between 10 and 30 nm.

According to a second aspect, the invention relates to a solar cell comprising a nanometric structure according to the first aspect, deposited on a substrate and in which the aimed for absorption spectral band is within the visible-near-infrared range.

According to a variant embodiment, the solar cell further comprises a transparent conductive layer disposed between the metal reflector and the absorber layer.

According to a variant embodiment, the solar cell also comprises a transparent conductive layer disposed between the absorber layer and the metal array or on the metal array and the absorber layer.

According to a variant embodiment, the transparent conductive layer is made of ZnO, ITO or SnO.

According a variant embodiment, the metal reflector is multi-layer, comprising a lower layer for adhesion to the substrate and an upper layer made of noble metal, such as gold, silver or aluminium.

According to a variant embodiment, the metal array is made of noble metal, such as gold, silver or aluminium.

According to a variant embodiment, the absorber layer comprises a semi-conductor material of type III-V, such as gallium arsenide or indium phosphide.

According to a variant embodiment, the absorber layer comprises a material from among amorphous silicon, CIGS and cadmium telluride.

According to a variant embodiment, the absorber layer comprises an organic material.

According to a variant embodiment, the solar cell comprises an asymmetric MIM type absorbent nanometric structure comprising:

a silver metal reflector;

an absorber layer made of GaAs less than 50 nm thick;

a metal array made of silver less than 30 nm thick, formed from pads or strips arranged periodically, the width of said pads or strips being between 80 and 120 nm, the linear filling factor being between 0.5 and 0.7.

According to a variant embodiment, the solar cell comprises an asymmetric MIM type absorbent nanometric structure comprising:

a silver metal reflector;

an absorber layer made of GaSb less than 50 nm thick;

a metal array made of silver less than 30 nm thick, formed from pads or strips arranged periodically, the period being between 270 nm and 330 nm and the linear filling factor being between 0.5 and 0.7;

a layer made of conducting transparent material arranged on the metal array.

According to a variant embodiment, the solar cell comprises an asymmetric MIM type absorbent nanometric structure comprising:

a silver metal reflector;

an absorber layer made of CIGS less than 50 nm thick;

a metal array made of silver less than 30 nm thick, formed from pads or strips arranged periodically, the period being between 500 and 550 nm and the linear filling factor being between 0.5 and 0.7;

a layer made of conducting transparent material arranged on the metal array.

For example, the layer made of transparent conductive material is ZnO:Al, less than 50 nm thick. The Applicant has shown an enhancement of the absorption in the near infrared visible spectrum associated with resonances in the layer of transparent conductive material deposited on the metal array.

According to a third aspect, the invention relates to a method for producing a solar cell according to the second aspect comprising:

depositing one or more layers of metal on the substrate to form the metal reflector,

depositing the absorber layer onto said metal reflector,

depositing a layer of resin and structuring the layer of resin to form elements of the array,

depositing metal forming the metal array and dissolving the resin.

According to a variant embodiment, the resin is structured by nano-imprint.

### BRIEF DESCRIPTION OF THE DRAWINGS

Other advantages and characteristics of the invention will become apparent from reading the description, illustrated by the following Figs.:

FIGS. 1A and 1B, diagrams respectively depicting example embodiments of a one-dimensional or two-dimensional absorbent asymmetric MIM structure according to the present invention;

FIG. 2, theoretical absorption curve calculated in a structure of the type in FIG. 1A, compared with the solar spectrum;

FIG. 3, diagram illustrating the various types of resonator implemented in the example of the structure in FIG. 2;

FIG. 4, diagram illustrating the dependence of the modal effective index as a function of wavelength for various types of plasmonic structure;

FIG. 5, diagram illustrating the dependence of the energy of excited resonances in the structure as a function of the width of the element of an array;

FIG. 6, diagram illustrating the dependence of the phase in reflection of a plane wave in a dielectric on a metal reflector as a function of wavelength for various types of dielectric;

FIGS. 7A, 7B, diagrams illustrating the dependence of energy of excited resonances in the structure as a function of the thickness of the absorber layer;

FIGS. 8A, 8B, experimental curves depicting absorption as a function of the angle of incidence in a one-dimensional asymmetric MIM structure;

FIGS. 9A, 9B, experimental curves depicting absorption as a function of the angle of incidence in a two-dimensional asymmetric MIM structure, in TM and TE polarisation, respectively;

FIGS. 10A and 10B, curve illustrating absorption in a two-dimensional asymmetric MIM structure according to the invention, respectively, as a function of the filling rate with constant period and as a function of the period, with constant filling rate;

FIG. 11, a curve depicting the absorption length in GaAs;

FIGS. 12A to 12D, diagrams of example embodiments of solar cells using an asymmetric MIM type nanometric structure according to the invention;

FIG. 13, curves depicting absorption measured in an asymmetric MIM structure comprising a GaAs absorber layer for various values of filling rate;

FIG. 14, a curve depicting the absorption calculated in an asymmetric MIM structure comprising an absorber curve made of GaSb;

FIG. 15, a curve depicting the absorption calculated in an asymmetric MIM structure comprising an absorber curve made of CIGS;

### DETAILED DESCRIPTION

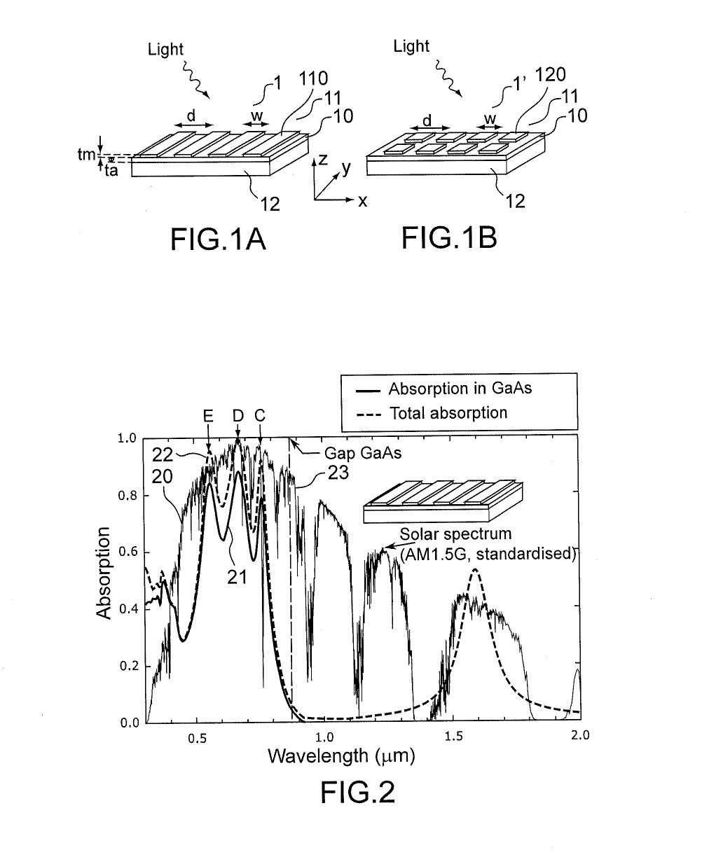

FIGS. 1A and 1B show two examples 1 and 1′, one dimensional and two dimensional respectively, of asymmetric MIM type nanometric structures according to the invention, intended to receive incident light the absorption of which is to be maximised in a given spectral band. Asymmetric MIM type structure (MIM being the abbreviation for metal/insulator/metal) is the name given to a multi-layer structure comprising at least one layer made of dielectric material between a metal array and a metal reflector, the metal array being of subwavelength dimensions and the reflector exhibiting a thickness greater than that of the metal skin (defined as the characteristic attenuation distance of an incident wave in the metal), such that it can be considered as semi-infinite in a propagation model of waves at the wavelengths under consideration. This combination of dielectric layer between a metal array and a semi-infinite reflector renders the structure asymmetrical. Included in dielectric materials here are insulating and semi-conductor materials, including doped semi-conductors.

In this type of structure, it is known to have a propagation of modes called ‘plasmon modes’ or surface plasmons, solutions to Maxwell equations at the metal/dielectric interfaces. The excitation of various plasmon modes under the effect of an incident light wave may occur if the resonance and coupling conditions are combined, these conditions depending on the geometry of the structure, and particularly those of the metal array (for example, see J. A. Schuller et al., “Plasmonics for extreme light concentration and manipulation”, Nature Materials 9, 193-204, 2010).

Each of the structures according to the invention comprises a layer of dielectric material 10 of refraction index nₐ, of thickness tₐ, arranged between a metal array 11 and a metal reflector 12. In the example of the one-dimensional structure of FIG. 1A, the array is formed from strips 110 of width w, of thickness tₘ, arranged according to a period d. In the example of FIG. 1B, the array is formed from square pads 120 of side w. The period along both dimensions is, for example, similar, referenced d. The dimensions of the period, of the strip (or pad) width, of the thickness of the dielectric layer and array are subwavelength, that is, less than the minimum wavelength of the aimed-for absorption spectral band. Period d is advantageously less than half the minimum wavelength so as to limit any loss of energy by diffraction over the array whatever the angle of incidence. Moreover, layer 10 is absorbent in the aimed-for absorption spectral band.

In a preferred application of the invention, in particular for application to solar cells, the structure is designed to receive sunlight and the aim is to optimise the absorption of the structure between around 500 and 800 nm. The layer is chosen in a material that is absorbent in this spectral band. Advantageously, as will be explained in more detail in what follows, a high-index material (typically greater than 3) will be chosen, enabling the thickness of the layer to be reduced. For example, the dielectric material is a semi-conductor material of type III-V (comprising one element in column III and one element in column V of the periodic table of elements), with a gap in the near-infrared, for example gallium arsenide (GaAs) or indium phosphide (InP). Although they have a lower index (typically between 1.5 and 2), organic polymers, for example based on fullerene derivatives, are similarly promising materials. Other materials such as cadmium telluride, amorphous silicon, microcrystalline silicon or polycrystalline silicon are also envisaged.

The metal array and metal reflector are made, for example, of silver, gold or aluminium, noble metals with low absorbency in the visible range. According to a preferred variant embodiment, the metal array may be made of gold and the metal, air-sealed reflector of silver, silver being liable to deterioration in contact with the atmosphere (sulfuration).

The Applicant has shown that, for solar cell application, with an aimed for absorption band in the visible range between 500 and 800 nm, advantageously, the width of strips (or pads) of the metal array will advantageously be chosen to be less than 150 nm, advantageously between around 80 and 120 nm, and the period less than 250 nm, advantageously between around 150 and 250 nm. The thickness of the absorber layer will be chosen as less than 100 nm, and the thickness of the metal array less than 30 nm, advantageously between around 15 and 25 nm. The metal reflector has a thickness greater than that of the metal skin, typically a thickness greater than 50 nm in the case that gold or silver is used. More details on the optimisation of the dimensions and choice of materials of the structure will be given in what follows.

FIG. 2 depicts the results of numerical simulations of a one-dimensional asymmetric MIM plasmonic structure according to the invention (shown as an insert in FIG. 2), of the type shown in FIG. 1A.

In this example, the absorber layer is made of gallium arsenide (GaAs), the real part of the index of which is around 3.5 (see E. D. Palik, Handbook of Optical Constants of Solids Academic, Orlando, 1985). Its thickness is 25 nm. The layer is arranged between a silver metal array the period of which is 200 nm, and the strip width of which is 100 nm. The thickness of the array is 15 nm. The metal reflector is made of silver.

The model used for these simulations is based on the exact modal method (for example, see S. Collin et al., ‘Efficient light absorption in metal-semiconductor-metal nanostructures, Appl. Phys. Letters 85, 194, 2004), with a TM polarised wave (magnetic field parallel to strips of the array).

The Applicant has provided evidence for a remarkable absorption in three spectral bands centred on 560 nm (resonance labelled E), 675 nm (resonance labelled D) and 760 nm (resonance labelled C) respectively. Curve 21 depicts the absorption calculated in the GaAs while curve 22 depicts the absorption calculated in the total structure. These two curves are compared with the standardised solar spectrum 20 (AM1.5G, here plotted in number of photons/m²/s/nm⁻¹ ). GaAs is advantageous, particularly in that it exhibits a gap of 1.42 eV at ambient temperature well suited for solar photovoltaic applications (for example, see T. Markwart and L. Castaner, Practical handbook of Photovoltaics, Elsevier, 2003), the record efficiency obtained experimentally for a single junction being 26.1% (theoretical maximum efficiency 32%). It is observed that the maximum absorption coincides with the maximum emission of the solar spectrum. The slight difference (less than 13%) between curves 21 and 22 over the entire visible range shows a very weak absorption by the metal array over the entire visible range, revealing excellent confinement of light in the GaAs active layer (and slight ohmic losses in the metal array). On average, 70% of incident photons are absorbed in the spectral range 500-800 nm, and 55% of photons, the energy of which is greater than the gap (embodied by the dotted line 23) are absorbed in the cell. A theoretical solar energy conversion efficiency of 17% (conversion efficiency of solar energy into electrical energy) is deduced, for a cell the external quantum efficiency of which, independent of polarisation, is given by curve 21 of FIG. 2 (assuming that the GaAs layer consists of a perfect p-n junction, the nonradiative recombinations being negligible and the internal quantum efficiency assumed to be equal to 1). The calculation of the theoretical efficiency is described, for example, in G. Araujo et al., ‘Limiting efficiencies of GaAs Solar cells’, IEEE Transactions on Electron Devices 37, 1402-1405, 1990 or W. Shockley et al., ‘Detailed balance limit of efficiency of p-n junction solar cells’, Journal of Applied Physics 32, 510-519, 1961.

The Applicant has shown that this remarkable absorption in an ultra-thin structure (less than 50 nm in this example) can be explained by a combination of resonances, the physical principles of which differ, and which can therefore be adjusted by changing independent parameters of the structure. Consequently, by adapting the various parameters of the structure, it is possible to optimise the position of the wavelengths around which are centred the absorption peaks in order to obtain the structure response for the intended application.

The multi-resonant structure according to the invention therefore enables a paradox to be resolved, which is that, in general, if the time for the photon to pass into the structure (that is, the optical path) is increased, the spectral width of the resonance is reduced.

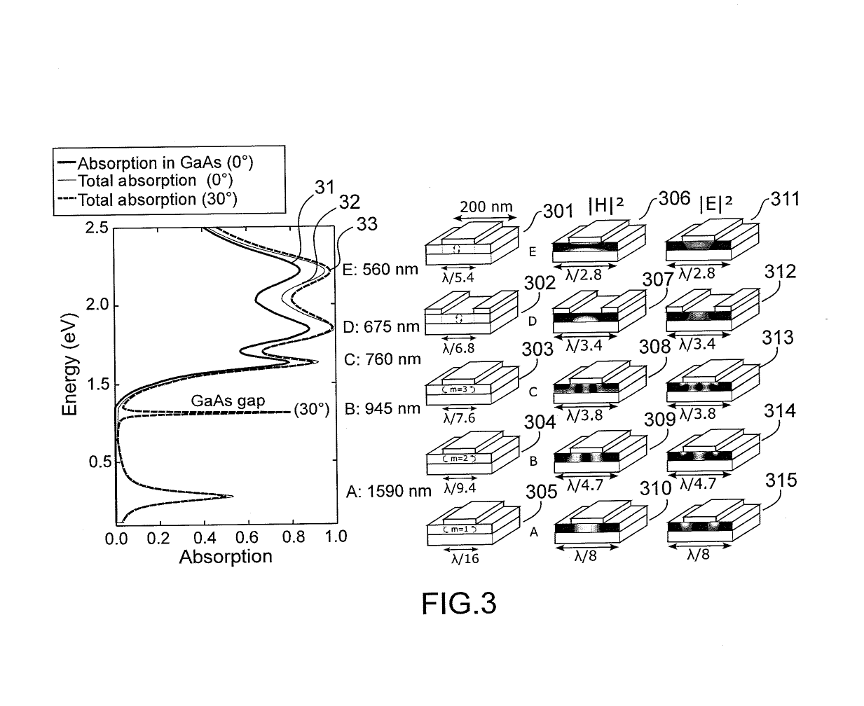

FIG. 3 again depicts the absorption spectra in GaAs (curve 31) and total (curve 32) at normal incidence, and total absorption (curve 33 dotted) for an angle of incidence of 30°. Here, the spectra are plotted against energy (the energy of the resonance is inversely proportional to the resonance wavelength). The nature of the various resonances, labelled A-E, is shown schematically by the right-hand part of FIG. 3 (diagrams 301 to 305, corresponding to resonances E, D, C, B and A, respectively). Electromagnetic field charts are shown by diagrams 306 to 315. The square modulus of magnetic field H (curves 306 to 310) shows the resonant cavity modes. For example, diagram 310 shows a first-order resonance, while diagrams 309 and 308 show a second-order and third-order resonance, respectively. It has been ascertained that order m=3 is advantageous in this example embodiment because it enables a resonance at 760 nm to be obtained, thus within the aimed-for absorption band. Diagrams 306, 307 show the fundamental order for resonances E and D, respectively. The square modulus of electrical field E (curves 311 to 315) in turn shows the location of the absorption in the cavities.

The Applicant has shown that each resonance can be modelled by a Fabry-Pérot resonator. The resonance condition of this resonator is generally written 1−r₁r₂e^{2ikh}=0 where k=2π(n_{eff}+ik_{eff})/λ is the wave vector, λ the wavelength, (n_{eff}+ik_{eff}) the complex effective index of the mode and r₁ and r₂ are the reflection coefficients at the ends of the resonator. Noting φ₁ and φ₂, the phases induced by these two reflections, the resonance condition is written 4 πhn_{eff}/λ+φ₁+φ₂=2 πp where p is an integer (p=±0, ±1, ±2, . . . ). For a given wavelength, the size h of the resonator is then given by the general equation:

$$h = λ \frac{2 π p - ( {φ}_{1} + {φ}_{2} )}{4 π {n}_{eff}} \qquad ( 1 )$$

In the case of a conventional, symmetrical Fabry-Pérot resonator, φ₁=φ₂=0 in the case of a dielectric surrounded by air, or φ₁=φ₂=±π in the case of a reflection on a metal with strong permittivity, for example silver, aluminium or gold in the infrared. The resonance condition is then simply written:

$$h = \frac{λ p}{2 {n}_{eff}} \qquad ( 2 )$$

The Applicant has shown that the resonances labelled A, B and C can be described by a plasmon mode resonance under the metal fingers (or strips) in the plane of the solar cell. The MIM structure therefore plays the role of a Fabry-Pérot resonator for a plasmon wave propagating along the x axis (parallel to the plane of the mirrors) and reflecting at the ends of the elements of the array. The Applicant has thus shown a ‘horizontal’ or ‘longitudinal’ resonant cavity, that is, one parallel to the plane of the array, the length of which is given by the width w of the element of the metal array and the index by the effective index n_{eff} of the mode propagating. The change of phase may be disregarded in a first approximation at the ends of the resonator, and the wavelengths of the first three resonances approximately follow the equation:

$$λ = \frac{2 {n}_{eff} w}{p} \qquad ( 3 )$$

with p=1, 2, 3 for A, B, C, respectively.

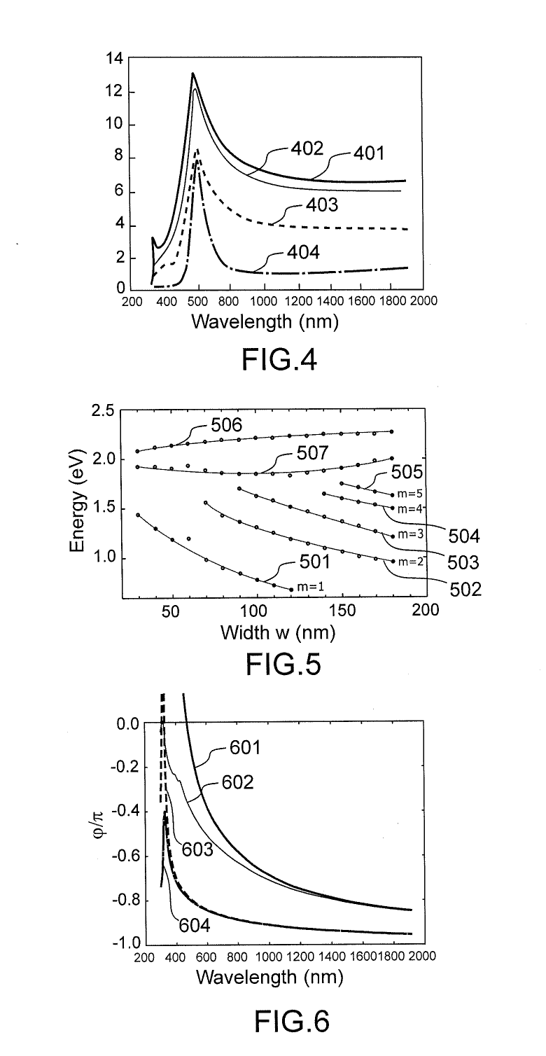

The plasmon modes have the particular feature of propagating with an effective index greater than that of the dielectric medium (see, for example, A. V. Zayats et al., ‘Nano-optics of surface plasmon polaritons’, Physics reports 408, 131-314, 2005). This effect is reinforced by coupling between a plurality of surface plasmons, as in the case of an MIM guide (here Ag—GaAs—Ag). This effect is illustrated in FIG. 4, where the Applicant has modelled the value of the real part of the effective index as a function of wavelength. The calculation method is described, for example, in S. Collin et al., ‘Waveguiding in nanoscale metal apertures’, Opt. Express 15, 4310-4320, 2007. Curve 401 is obtained by modelling a semi-infinite multi-layer structure, with three interfaces (air/silver interface, silver/GaAs interface, GaAs/silver interface), with a thickness of 25 nm for the GaAs and 15 nm for the silver. Curve 402 is obtained with a structure having two interfaces (silver/GaAs interface, GaAs/silver interface). Curve 403 is obtained with a structure having only a single GaAs/silver interface. Curve 404 represents the effective index of a mode obtained in a structure exhibiting two interfaces: air/GaAs and GaAs/silver. Curve 401 shows that in the visible range, the effective index reaches values of the order of 10, and it stays at a very high level (around 6, being double the index of GaAs) in the near-infrared range (1-2 μm). At the shorter wavelengths, the effective index breaks down and the plasmon mode disappears. The large difference reached by the real part of the effective index between curves 401, 402 on the one hand and 403, 404 on the other comes from the existence in the first case of coupling of two plasmon modes at the silver/GaAs and GaAs/silver interfaces. In the case of curve 401, the effective index is still slightly greater if a thin metal thickness is chosen because a 3rd coupling is produced with the air/silver plasmon mode.

Thus, the Applicant has shown that with a width of the strip of the metal array w=100 nm, three resonance peaks A, B, C at 1590 nm, 945 nm and 760 nm, respectively, are obtained, corresponding to modes m=1, m=2 and m=3. The optimisation of the parameters of the structure to obtain a resonance corresponding to mode m=3 is particularly advantageous as it enables a resonance at a wavelength of the visible spectrum with a low value of the width w of an element of the metal array (around 100 nm).

FIG. 5 illustrates the influence of the width w of elements of the metal array on the resonance energy (inversely proportional to the wavelength). Curves 501 to 505 represent the energy as a function of the width w for the first 5 plasmon modes (m=1 to 5), in an asymmetric MIM plasmonic structure of the type of FIG. 1A (calculation conditions identical to those of FIG. 2). For a given mode, by widening the cavity (increasing w), a shift is effected towards low energies and thus the greatest wavelengths.

The Applicant has shown, for resonances D and E, a mechanism different from that shown in the case of resonances A, B and C.

Considering equation (2), it appears that with an index of the order of 3.5 (index of GaAs), the smallest resonator at 700 nm has a size of 100 nm and the following order resonates at λ=350 nm. It is therefore not possible to get multiple resonance in a resonator of a size less than 100 nm. The Applicant has shown that in an asymmetric MIM structure, with an absorber layer of a given index and by adequately choosing the thickness of the layer, it is possible to obtain one or even more resonances in the visible range. Indeed, it appears that the coefficient of reflection on an interface between a high-index semi-conductor (around 3 or more) and a metal such as silver, aluminium or gold, for example, deviates from its usual values for wavelengths of 600 nm. This is shown in FIG. 6, which depicts the phase upon reflection as a function of the wavelength of a plane wave propagating in the GaAs onto a silver mirror assumed to be infinite, calculated using Fresnel coefficients (curve 602). The function giving the phase upon reflection can be approximated by the function (−1+2 n_{GaAs}/k_{Ag}) where n_{GaAs} is the real part of the gallium arsenide index and k_{Ag} is the imaginary part of the silver index (curve 601). For comparison, curves 604 and 603 represent, respectively, the phase upon reflection of a plane wave propagating in a vacuum onto a silver mirror and the function (−1 +2/k_{Ag}) which approximates the calculated function of the phase upon reflection. Curve 602 shows that at large wavelengths, the phase is close to π (in the case of a perfect metal). On the other hand, around 600 nm, the phase goes through π/2. Ignoring the phase change of the wave reflecting on the metal array (either a reflection on air between the elements of the array or reflection on the very thin metal layer under the elements of the array), equation (1) then becomes, at order 0:

$$h = \frac{λ}{8 {n}_{a}} \qquad ( 4 )$$

where nₐ is the index of the absorbent material (such as GaAs).

For an index nₐ=4, there therefore exists a ‘vertical’ Fabry-Pérot cavity (that is, a cavity perpendicular to the plane of the array) exists between the metal array and the metal reflector which resonates at a wavelength of 640 nm for an absorption layer thickness tₐ=20 nm. This resonance exists at the fundamental Fabry-Pérot order (order p=0 in equation (1)), contrary to the longitudinal cavity shown for plasmon resonances A, B and C.

Moreover, it can be shown that curve 601 exhibits few variations depending on the metal used and the absorbent material.

As can be seen in FIG. 6, when the wavelength moves away from 600 nm, the phase will substantially move away from π/2, consequently changing the relationship between the wavelength of the resonance and the thickness of the dielectric layer given by equation (1).

The Applicant has shown that in an asymmetric MIM plasmonic structure of the type of FIG. 1A, two resonances of this type could be shown (absorption peaks D and E of FIG. 3). This effect comes from a first ‘vertical’ Fabry-Pérot cavity (perpendicular to the plane of the array) under the elements of the array (absorption peak E) and from a second vertical Fabry-Pérot cavity under the spaces between the elements of the array (absorption peak D), thus forming a ‘split’ cavity of order 0. The difference between the two resonance wavelengths can be explained, for identical thickness of the absorption layer, by the conditions at the various limits on the upper end of the cavity. By adjusting the thickness of the absorption layer, it is therefore possible to generate two absorption peaks within the visible range, at wavelengths less than the resonance of the plasmonic cavity. According to a variant embodiment, it is possible even to vary the thickness of the absorption layer inhomogeneously, for example by choosing a different thickness under the elements of the array to that under the spaces between the elements of the array, so as to improve the position of the absorption peaks.

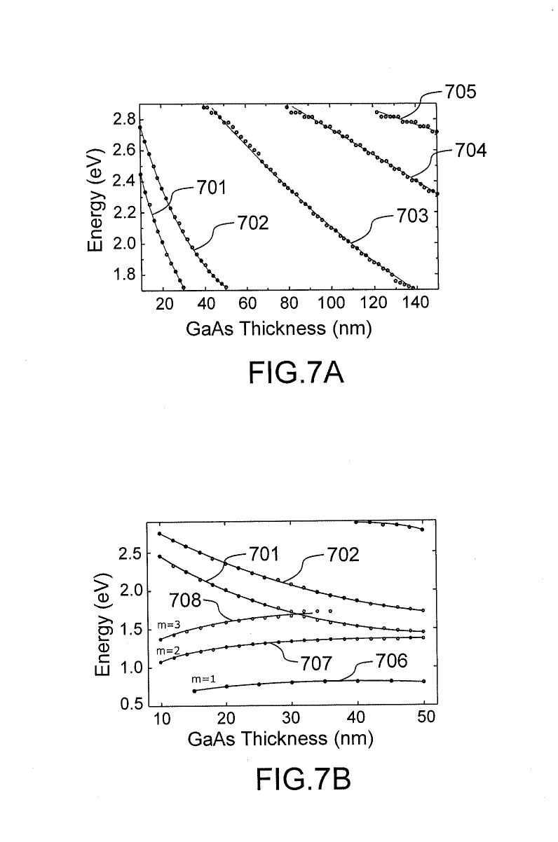

The change of vertical resonance as a function of thickness tₐ of the absorber layer is illustrated in FIG. 7A for a GaAs layer (same conditions as that of FIG. 2). Curves 701 and 702 show the energy response of the ‘split’ vertical Fabry-Pérot cavity of order 0. Curves 703 to 705 show the energy responses for orders 1 to 3 of the vertical Fabry-Pérot cavity, respectively.

Curve 7B also depicts the curves calculated from the energy as a function of the thickness of the absorber layer, but for lower thickness values. Curves 701 and 702 of the energy for the vertical Fabry-Pérot cavity of order 0 and also curves 706 to 708 of the longitudinal plasmonic cavity energy of orders m=1 to 3, respectively, are also shown. It can be seen that for the very low thicknesses, the effective index coming into play for plasmon resonances (resonances A, B, C) decreases when the thickness of the absorber layer increases, this being associated with a decrease in coupling between the plasmons of the two Ag/GaAs interfaces. A slight spectral shift of these resonances results, which are mixed with vertical Fabry-Pérot resonances for the weakest energies, near the gap (around 1.4-1.6 eV). FIG. 7B shows that in an asymmetric MIM plasmonic structure, by selecting a material for the given absorption layer by its thickness, multiple resonances can be generated within the desired spectral band. In particular, in this example, for a layer thickness of GaAs of around 25 nm, the 5 resonances A, B, C, D, E are obtained, of which 3 resonances C, D, E are within the spectral band 500-800 nm.

Moreover, the Applicant has shown that the width of the elements of the array has little effect on the resonance at the fundamental order of the vertical Fabry-Pérot cavity. This becomes apparent in particular in FIG. 5, where curves 506, 507 show the energy of the ‘split’ vertical Fabry-Pérot cavity as a function of thickness w, respectively. This is remarkable in that it will be possible to influence the wavelengths of the plasmon resonances by changing the parameter w without affecting the wavelengths of ‘vertical’ resonances. On the contrary, the vertical resonances will be particularly sensitive to the thickness of the absorption layer, while the plasmon resonances will be less so.

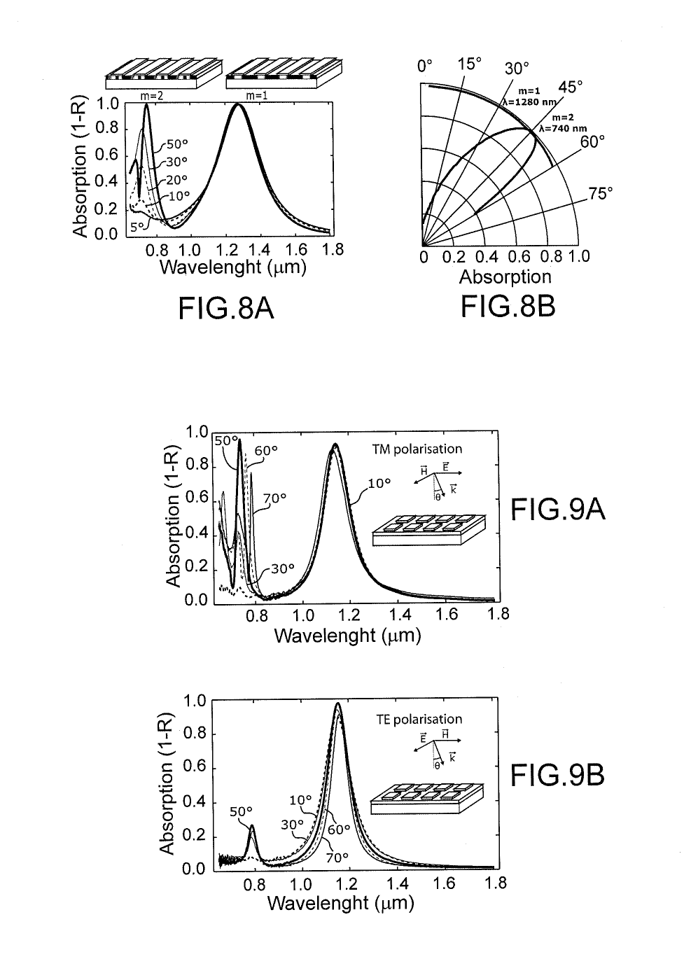

FIGS. 8A and 8B illustrate the angular dependence of a one-dimensional asymmetric MIM structure according to the invention using experimental curves (of the type of FIG. 1A).

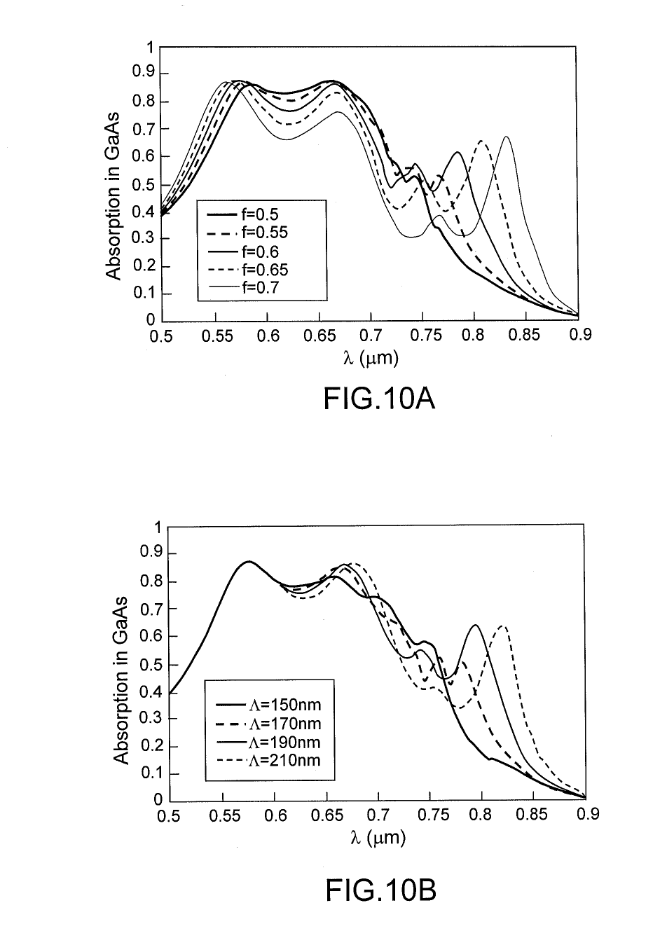

These curves have been obtained with a layer of SiO₂ (silicon dioxide) with a thickness of 20 nm, deposited on a glass substrate covered with a layer of gold. The gold metal array, is manufactured by a technique called nano-imprint described, for example, in S. H. Ahn and L. J. Guo, ‘High-Speed Roll-to-Roll Nanoimprint Lithography on Flexible Plastic Substrates’ (Advanced Materials 20, 2044-2049, 2008). The geometric parameters of the array (period of 400 nm, width of elements w=200 nm, and thickness 20 nm) have been optimised to exhibit two resonant modes between 600 and 1800 nm. Although silicon dioxide is not absorbent in the visible range, and is thus not suitable for the solar-cell application, these experimental curves show the geometric conditions enabling a plasmonmode resonance with almost perfect absorption, within a wide-angle band. Reflection measurements have been taken between 3° and 60°, with TM polarisation (magnetic field along the y axis). Excitation of the fundamental mode (m=1) of the MIM structure shows an almost perfect absorption at λ=1280 nm (>98%) whatever the angle of incidence. This insensitivity to the angle of incidence is linked to the symmetry of the mode in relation to a plane of symmetry of the structure (also true for m=3). The MIM type nanostructure acts as a Fabry-Pérot resonator for the plasmonic wave propagating along the x axis, and reflects at the ends of the elements of the array. Here, the high effective index of the plasmon mode is due to very strong coupling between the very thin metal array and the semi-infinite metal reflector. The Applicant has shown that the resonance wavelength is determined primarily by the width w of the elements (see FIG. 5) and, to a lesser degree, by the thickness of the dielectric layer which influences coupling and thus the effective index of the mode. Here it must be noted that the layer thickness is not suitable for obtaining a resonance from a vertical Fabry-Pérot type cavity between the metal reflector and the metal array. Coupling can also be modified by changing the filling rate of the array, as shown in FIG. 10A.

FIGS. 9A and 9B illustrate the angular dependence of a two-dimensional asymmetric MIM structure (of the type in FIG. 1B) with TM and TE polarisation, respectively. The experimental conditions are the same as those of FIGS. 8A and 8B. The structure comprises square pads arranged according to a two-dimensional periodic structure, with a period according to each of the dimensions of 400 nm and a width of pads of 250 nm (thickness 20 nm). It is remarkable to note that here 90% of the absorption is obtained in ultra-small nanocavities (volume of the order of λ³/1000), both for TE and TM modes. This shows the feasibility of a two-dimensional asymmetric MIM plasmonic structure, which will have an obvious advantage for solar-cell applications, as there will be no filtering in polarisation and thus a better efficiency. It is to be noted that the vertical Fabry-Pérot resonators shown in the multi-resonant structure according to the invention are also insensitive to polarisation.

FIGS. 10A and 10B show simulations of absorption as a function of wavelength in a two-dimensional structure of the type in FIG. 1B, wherein the absorber layer is made of GaAs and exhibits a thickness of 25 nm, the thickness of the metal array is 20 nm, the period by default is 180 nm, and the filling rate (ratio of the width of the pad to the period, measured according to one dimension) is 0.6. FIG. 10A depicts the results obtained for equal period, by varying the filling rate (f). FIG. 10B depicts the results obtained at constant filling rate, by varying the period (Λ). The calculation method is the RCWA method describe, for example, in P. Lalanne et al., ‘Surface plasmons of metal surfaces perforated by nanohole arrays’, Journal of optics A: Pure and Applied Optics 7, 422-426, 2005.

These curves show, as in the example of a one-dimensional structure, a wide band absorption in the visible range with the presence of three absorption peaks (corresponding to the peaks C, D, E previously described). Furthermore, if the absorption peaks due to the double resonance of the ‘vertical’ Fabry-Pérot cavity are only slightly variable depending on the geometry of the metal array elements, a variation of the absorption peak of the plasmonic resonator is observed, as a function of wavelength and as a function of amplitude simultaneously, linked to the dimension of the resonator (w) and the coupling quality in the cavity depending on its geometry. In particular, an increase in absorption due to the plasmon resonance is observed with the increase of filling rate apparently due to a better coupling while the absorption due to the under-space ‘vertical’ resonance (resonance D) decreases, apparently due to the reduction in space between the elements.

The Applicant has shown that in this example the best efficiency of a solar cell which would be produced with this structure is obtained for a filling rate f=0.6 and a period of d=180 nm.

Thus, by choosing an asymmetric MIM structure comprising a GaAs layer less than 50 nm thick, for example between 20 and 30 nm, typically around 25 nm, said GaAs layer being comprised between a metal reflector, for example made of silver, and a metal array formed from strip type elements or pads also made of silver arranged periodically, FIGS. 7A and 7B show the presence of one or more vertical resonances of the order 0 in the absorber layer for wavelengths comprised in the near-infrared visible spectral band. By choosing the parameters suitable for the metal array, typically a thickness less than 30 nm, a width of the elements forming the array of between 80 and 120 nm, and a linear filling factor of between 0.5 and 0.7, a horizontal plasmon resonance of order 3 (see FIG. 5) is also observed in the near-infrared visible spectral band. A multi-resonant structure particularly well suited to production of a solar cell may thus be obtained because it has a wide absorption in the near-infrared visible spectrum, an absorption the physical mechanisms of which can be explained both by a horizontal plasmon resonance but also by one or more vertical resonances in the GaAs layer.

Although most of the curves simulated above have been obtained with GaAs as an absorbent dielectric material, it is evident that other materials are very promising for obtaining a multi-resonant absorbent asymmetric MIM structure such as defined above. In particular, it will be possible to seek materials such as indium phosphide (InP) or amorphous silicon (a-Si:H), which will enable structures to be designed with dielectric layers between 50 and 100 nm, making it much easier to obtain a junction for a solar cell with current technological modalities.

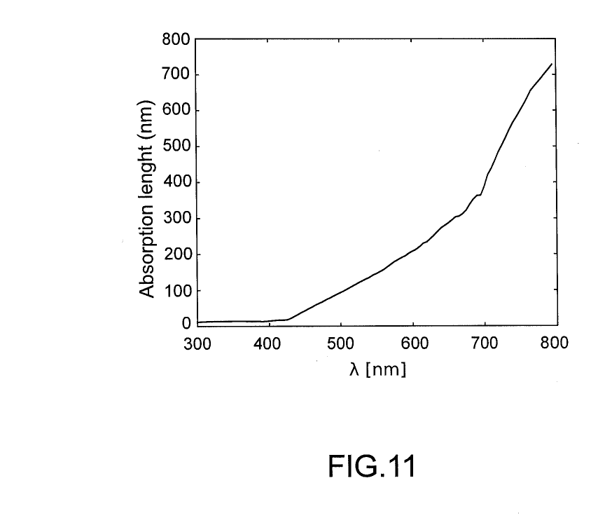

Whatever the dielectric material chosen, it will be preferable to choose an absorber layer thickness less than the absorption length of the dielectric material of which it is formed to obtain the aimed-for resonance of a Fabry-Pérot cavity between the metal array and the metal reflector. The absorption length of the material is defined by the depth in the material at which the intensity of an incident light wave of given wavelength is divided by e. FIG. 11 depicts, for example, the absorption length as a function of wavelength for GaAs.

Advantageously, the thickness of the absorber layer is of the order of magnitude of the thickness of the metal skin forming the dielectric array or up to twice the thickness of the skin, to promote coupling of plasmon modes to metal/dielectric, dielectric/metal interfaces and to obtain elevated modal effective indices.

According to a variant embodiment, the nanometric structure further comprises a non-absorbing dielectric layer, arranged between the absorber layer and the metal array to adjust the spacing between the metal array and the metal reflector and thus to adjust the resonance wavelength. The dielectric layer may or may not encapsulate the metal array.

Although the results have been presented in one-dimensional or two-dimensional structures with elements formed from strips or square pads, the invention is not limited to these types of pattern and other patterns may be envisaged as long as a periodic structure is preserved.

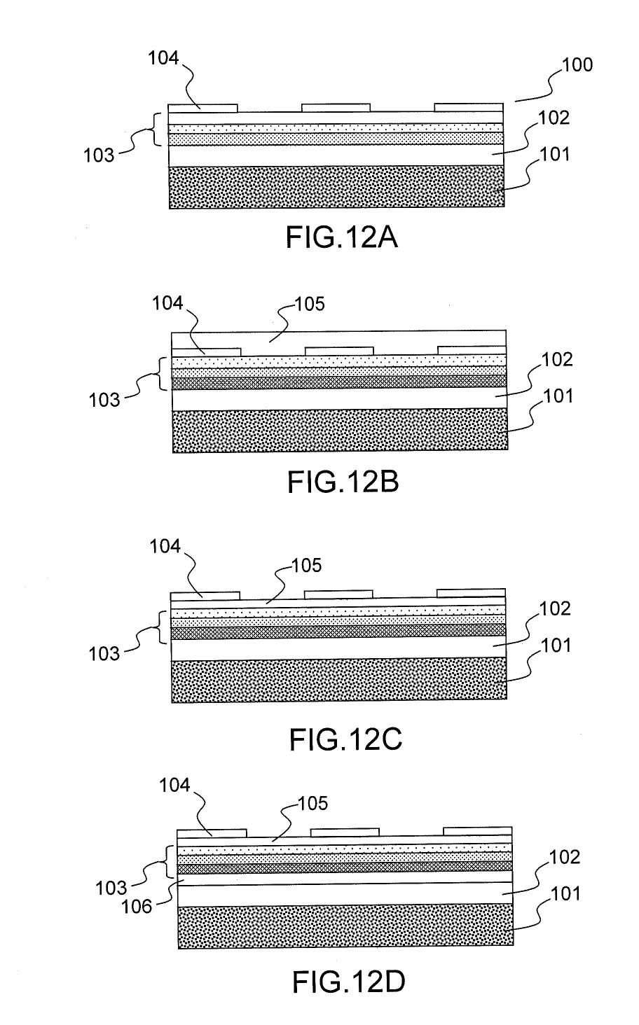

FIGS. 12A to 12D show embodiment examples of solar cells 100 obtained with an asymmetric MIM type structure according to the invention.

The ultra-thin MIM solar cells can be manufactured on a substrate 101 covered with one or more metal layers 102 forming the metal reflector, itself covered with layers forming the absorber layer 103. The metal array 104 is deposited on the absorber layer. In the example of FIG. 12D, a transparent conductive layer 106, for example of type TCO (abbreviation for ‘transparent conducting oxide’) is deposited between the metal reflector and the absorber layer. According to a variant embodiment, a transparent conductive layer 105 can also be deposited on the metal array (FIG. 12B) or between the metal array and the absorber layer (FIGS. 12C, 12D).

The substrate 101 is arbitrary, for example formed of any material such as glass, or metal or plastic sheet or film.

In the case of a metal reflector composed of several layers, the lower layer in contact with the substrate will be able to promote adhesion (for example made of chrome or titanium), and the upper layer in contact with the absorber (case of Figs. A to C) or with the TCO layer (case of Fig. D) shall be chosen for its optical properties (preferably a noble metal of type Ag, Al, Au, etc.) and electrical properties (inferior contact for conducting the current and Schottky or ohmic contact with the absorber). These metals will be able to be deposited by vacuum evaporation assisted by electron gun, by sputtering or by electrolytic growth.

The absorber 103 is, for example, formed of a semi-conductor material having a direct gap, or behaving as a semi-conductor material having a direct gap, such as gallium arsenide (GaAs), indium phosphide (InP), copper and indium selenide (CuInGa(Se,S)2 or CIGS), cadmium telluride (CdTe) or hydrogenated amorphous silicon (a-Si:H), for example. It comprises, for example, a p/p+ doped layer, an i intrinsic layer, and an n/n+ doped layer, or even uniquely two p and n doped layers, or even a p or n layer and an intrinsic layer forming a Schottky contact with the metal (upper or lower). The p (n) layer can be the lower (upper) layer or vice versa. The absorber can also comprise a hetero structure (different materials forming, for example, the various n and p layers). The absorber can also be deposited according to known methods—for example, see A. Shah et al. ‘Photovoltaic Technology: The Case for Thin-Film Solar Cells’, Science, 285, 692-698, 1999 or J. J. Schermer et al., ‘Photon confinement in high-efficiency, thin-film III-V solar cells obtained by epitaxial lift-off’, Thin Solid Films, 511, 645-653, 2006 for depositing by the ‘lift-off’ technique.

The metal array can be manufactured by lift-off according to the procedure comprising the following steps:

deposition of a photosensitive or electrosensitive resin onto the absorber, then insolation of the resin by UV photolithography or interference lithography, or by electronic lithography.

development of the resin, dissolution of insolated parts.

deposition of the metal forming the metal array (by evaporation, by sputtering, etc.), the metal is deposited on the absorber at the locations where the resin has been insolated,

lift-off by dissolution of the resin, only the metal deposited directly onto the absorber remains, forming an array according to the insolated pattern in the resin.

According to a variant embodiment, the resin may also be structured by nano-imprint. In this case, the metal arrays are, for example, produced by soft nano-imprint assisted by UV. A PMMA resin layer of 200 nm thickness is deposited onto the metal reflector/absorber assembly, then a 10-nm thin layer of germanium, and finally a layer of photosensitive liquid resin 100 to 150 nm thick used for the nano-imprint stage. This stage of moulding, or nano-imprint, is produced in a press with a silicone mould under very low pressure, and the resin is cross-linked by UV insolation. The structures obtained are transferred into the germanium layer and the PMMA resin by reactive ion etching. This assembly of three layers is used to produce metal arrays by lift-off: a layer of gold is deposited on the sample, then the PMMA resin is dissolved in a solvent, leaving only the gold nanostructures on the surface.

The transparent conductive layer (105, FIG. 12B) can be deposited onto the structure by evaporation, sputtering or electrolytic growth, for example. The transparent conductive materials used may be ITO (indium-tin oxide), ZnO:Al (zinc oxide doped with aluminium) and SnO2 (tin dioxide, which can be doped with iron, for example).

In another possible embodiment, the transparent conductive dielectric layer is deposited on the absorber, and the metal array is deposited on the transparent conductive dielectric layer (case C and D).

The collection of charges in the cell is done by the metal contact of the lower part (metal reflector) and by the array and/or the transparent conductive layer.

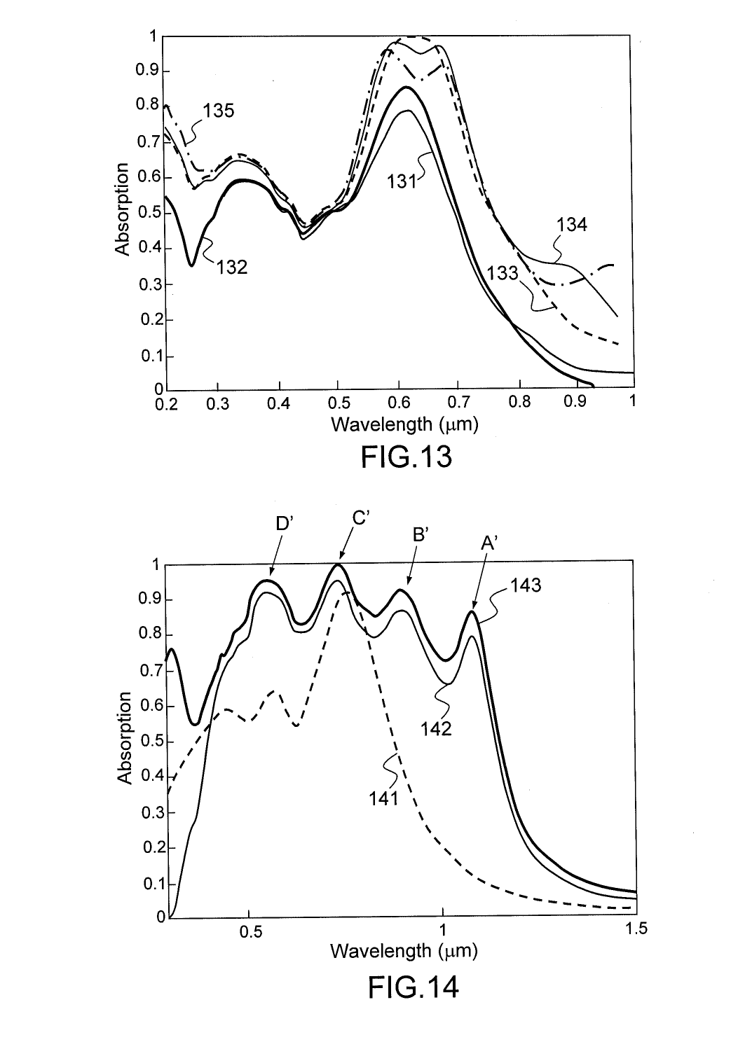

FIG. 13 illustrates the first experimental results obtained with a 25 nm GaAs absorber layer transferred onto a 200 nm gold mirror. The metal array is made of gold, produced by electronic lithography with a chrome adhesion layer. The metal array comprises an assembly of square pads arranged periodically with a period of approximately 200 nm and various values of the linear filling rate, equal to the dimension of the pad divided by period. In FIG. 13, the various curves are obtained from the measures of reflectivity at normal incidence of the structure. Curve 132 represents the measured absorption of a 25 nm layer of GaAs on gold (without presence of the metal array) while the layer 131 represents the absorption of GaAs calculated under the same conditions. Curves 131 and 132 almost completely overlap, which shows the quality of the GaAs layer transferred. On curves 131, 132, a single peak characteristic of a vertical resonance in the GaAs is observed. This intermediate stage, in particular, enables the thickness of the absorber layer to be validated. Curves 133, 134 and 135 show the absorption of the complete structure (reflector-absorber layer-metal array) for filling factors varying from 0.5 to 0.7, respectively. The splitting of the peak associated with vertical resonance is observed on the appearance of a third peak associated with the horizontal plasmon resonance which is shifted towards the red as the filling factor increases. The results of the numerical simulations shown above are also verified (for example, see FIGS. 10A, 10B).

Apart from GaAs, the Applicant has shown remarkable results with other absorbers.

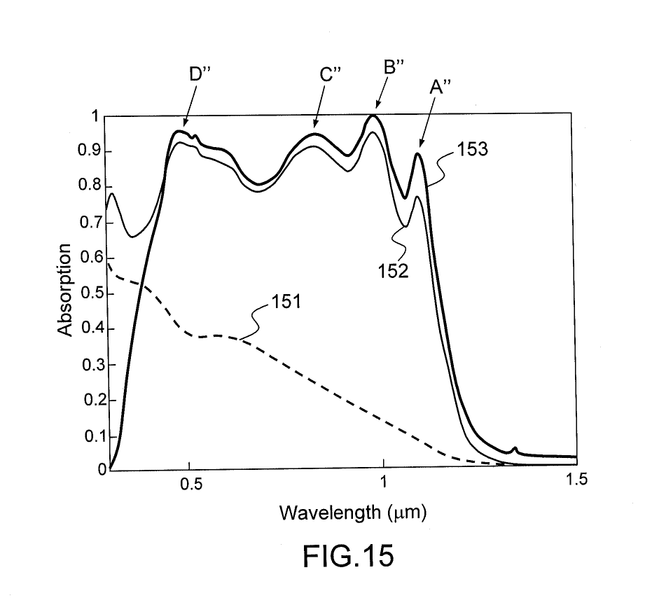

FIGS. 14 and 15 therefore show numerical results obtained respectively with GaSb (gallium antimonide) and CIGS.

In FIG. 14, curve 143 depicts the total absorption of an asymmetric MIM structure comprising a stacking of several layers, one layer of which is of 25 nm GaSb. The absorber layer is comprised between a silver metal reflector and a silver metal array of thickness 25 nm, formed from square pads arranged periodically with a period of 300 nm and a filling factor of 0.56. Moreover, the structure comprises a layer of transparent conducting material of type ZnO:Al, of thickness 50 nm, deposited on the metal array. Curve 143 shows a remarkable absorption spectrum in the visible range with multi-resonances characterised by peaks A′, B′, C′, D′. The Applicant has shown the existence of a horizontal plasmon resonance of order 3 in the absorber layer at 1100 nm (peak A′). Vertical resonances in the GaSb layer have been shown at 740 nm and 900 nm (at 900 nm, the resonance is located between the pads). Another remarkable peak is shown in this structure at 520 nm, which the Applicant has shown to correspond to a vertical resonance in the layer of ZnO:Al. In FIG. 14, curve 142 depicts the absorption calculated as a function of wavelength uniquely in the active layer of GaSb. The comparison between curves 142 and 143 show the absorption in the metal array and the ZnO:Al layer. Thus, it can be verified that in the near-infrared visible spectrum, the absorption of the structure results mainly from the absorption in the GaSb layer. Curve 141 shows the absorption in the GaSb without the presence of the metal array. This curve shows a single vertical resonance. The Applicant has thus shown, in such a structure, a theoretical short-circuit current Jsc=36.7 mA/cm² for the structure with array as opposed to Jsc=24.5 mA/cm² for the structure without array, being an increase of 50%. The short-circuit current Jsc equal to the theoretical current density calculated for illumination corresponding to the standardised solar spectrum AM1.5G is characterised by the performance of a solar cell obtained with such a structure. These results are remarkable for such a thin layer.

Thus, the Applicant has shown that an ultra-thin solar cell at very high absorption in the visible range, characterised by multi-resonances between 500 nm and 1000 nm, could be obtained owing to a multi-layer structure of the type described above comprising a GaSb layer and by choosing the characteristic parameters of the structure (mainly the width of the elements of the array, the linear filling factor, the thickness of the absorber layer and that of the upper layer in transparent conductive material). In particular, the GaSb layer will be chosen advantageously less than 50 nm, comprised between a metal reflector advantageously made of silver and a metal array also preferably made of silver, with a thickness less than 30 nm, formed from elements of the type strips or pads arranged periodically with a period advantageously comprised between 270 and 330 nm and a linear filling factor preferably comprised between 0.5 and 0.7. The layer made of transparent conductive material is advantageously made of ZnO:Al, with a thickness between 40 and 60 nm.

In FIG. 15, curve 153 depicts the total absorption of an asymmetric MIM structure comprising a stacking of several layers, one layer of which is made of 45 nm CIGS. The absorber layer is comprised between a silver metal reflector and a silver metal array of thickness 20 nm, formed from square pads arranged periodically with a period of 530 nm and a filling factor of 0.55. Moreover, the structure comprises a layer of transparent conductive material of type ZnO:Al, of thickness 50 nm, deposited on the metal array. Curve 153 shows a remarkable absorption spectrum in the visible range with multi-resonances characterised by peaks A″, B″, C″, D″. The Applicant has shown the existence of a horizontal plasmon resonance of order 3 in the absorber layer at 1100 nm (peak A″). A vertical resonance of the order 0 in the GaSb layer has been shown at 990 mm (peak B″). Wide absorption peaks around 490 nm (D″) and 830 nm (C″) corresponding to vertical resonances in the ZnO:Al layer have, moreover, been shown. In FIG. 15, curve 152 depicts the absorption calculated in the CIGS layer for a structure identical to that of curve 153. By way of comparison, curve 151 depicts the absorption calculated as a function of wavelength in a CIGS absorber layer deposited on molybdenum without the presence of the metal array. The Applicant has shown a theoretical short-circuit current of Jsc=37.7 mA/cm² for the structure with array (silver reflector-CIGS layer-metal array-ZnO:Al) as opposed to Jsc=13.2 mA/cm² for the structure without array on molybdenum, being an increase of 180%.

There, too, the Applicant has shown that an ultra-thin solar cell with very strong absorption in the visible range, characterised by multi-resonances between 500 nm and 1000 nm could be obtained owing to a multi-layer structure of the type previously described comprising a CIGS layer and by choosing the characteristic parameters of the structure. In particular, the CIGS layer will be chosen advantageously less than 50 nm, comprised between a metal reflector advantageously made of silver and a metal array also preferably made of silver, of thickness less than 30 nm, formed from strip- or pad-type elements arranged periodically with a period advantageously comprised between 500 and 550 nm and a linear filling factor preferentially between 0.5 and 0.7. The layer made of transparent conductive material is advantageously made of ZnO:Al, with a thickness between 40 and 60 nm.

Although described using a certain number of detailed example embodiments, the structure and method of producing the structure according to the invention comprise different variants, modifications and developments which will be obvious to the person skilled in the art, it being understood that these different variants, modifications and developments fall within the scope of the invention, as defined by the claims below.

1. An asymmetric MIM type absorbent nanometric structure for receiving a wide-band incident light wave the absorption of which is to be optimised within a given spectral band in the near-infrared visible range, comprising:
an absorbent dielectric layer in said spectral band, of subwavelength thickness, arranged between a metal array formed from metal elements periodically arranged with a subwavelength period and a metal reflector, wherein
the metal elements forming the metal array exhibit at least one dimension suitable for forming, between the metal array and the metal reflector, under the elements of the array, a plasmonic resonator forming a Fabry-Pérot type longitudinal cavity resonating at a first wavelength of the aimed-for spectral absorption band, and
the absorber layer exhibits, between the metal array and the metal reflector, at least one first thickness suitable for forming at least one first Fabry-Pérot type vertical cavity, resonating at a second wavelength of the aimed-for spectral absorption band.

2. The nanometric structure according to claim 1, wherein the absorber layer exhibits a first thickness under the elements of the array and a second thickness under the spaces between the elements of the array, which thicknesses are suitable for forming a first and a second Fabry-Pérot type vertical cavity resonating at two distinct wavelengths of the aimed-for spectral absorption band.

3. The nanometric structure according to claim 2, wherein the first and second thicknesses are substantially identical.

4. The nanometric structure according to claim 1, wherein the width of the elements of the metal array is suitable for obtaining a plasmon mode of the order m=3.

5. The nanometric structure according to any claim 1, also comprising a non-absorbing dielectric layer in the aimed-for absorption spectral band, arranged between said absorber layer and the metal array and/or encapsulating the metal array, enabling the thickness between the metal array and the metal reflector to be adjusted.

6. The nanometric structure according to claim 1, wherein a period of the metal array is less than half the minimum wavelength of the aimed-for absorption spectral band.

7. The nanometric structure according to claim 1, wherein the metal array is one-dimensional, formed from strips, or two-dimensional, formed from pads.

8. The nanometric structure according to claim 7, wherein the width of said strips or said pads is less than 150 nm.

9. The nanometric structure according to claim 1, wherein the thickness of the metal elements is less than 30 nm.

10. A solar cell comprising a substrate and a nanometric structure according to claim 1 deposited on said substrate, wherein the aimed-for spectral absorption band is in the visible-near-infrared range.

11. The solar cell according to claim 10, further comprising a transparent conductive layer disposed between the metal reflector and the absorber layer.

12. The solar cell according to claim 10, further comprising a transparent conductive layer disposed between the absorber layer and the metal array or on the metal array and the absorber layer.

13. The solar cell according to claim 11, wherein the transparent conductive layer comprises one selected from the group consisting of ZnO, ITO or SnO.

14. The solar cell according to claim 10, wherein the metal reflector is multi-layer, comprising a lower layer for adhesion to the substrate and an upper layer made of one selected from the group consisting of gold, silver or aluminium.

15. The solar cell according to claim 10, wherein the metal array is made of one selected from the group consisting of gold, silver or aluminium.

16. The solar cell according to claim 10, wherein the absorber layer comprises a material belonging to a type III-V semi-conductor selected from the group consisting of amorphous silicon, CIGS, cadmium telluride or an organic material.

17. The solar cell according to claim 10, wherein the absorbent nanometric structure comprises:
a silver metal reflector;
an absorber layer made of GaAs with a thickness less than 50 nm; and
a metal array made of silver with a thickness less than 30 nm, formed from pads or strips arranged periodically, the width of said pads or strips being between 80 and 120 nm, the linear filling factor being between 0.5 and 0.7.

18. The solar cell according to claim 10, wherein the absorbent nanometric structure comprises:
a silver metal reflector;
an absorber layer made of GaSb of a thickness less than 50 nm;
a metal array made of silver of a thickness less than 30 nm, formed from pads or strips arranged periodically, the period being between 270 nm and 330 nm and the linear filling factor being between 0.5 and 0.7; and
a layer made of conducting transparent material arranged on the metal array.

19. The solar cell according to claim 10, wherein the absorbent nanometric structure comprises:
a silver metal reflector;
an absorber layer made of CIGS with a thickness less than 50 nm;
a metal array made of silver with a thickness less than 30 nm, formed from pads or strips arranged periodically, the period being between 500 and 550 nm and the linear filling factor being between 0.5 and 0.7; and
a layer made of conducting transparent material arranged on the metal array.

20. The solar cell according to claim 18, wherein the layer made of conducting transparent material is made of ZnO:Al, less than 50 nm thick.

21. A method for manufacturing a solar cell according to claim 10, comprising:
deposition of one or more layers of metal on the substrate to form the metal reflector;
deposition of the absorber layer onto said metal reflector;
deposition of a layer of resin and structuring the layer of resin to form elements of the array; and
deposition of metal forming the metal array and dissolving the resin.

22. The manufacturing method according to claim 21, wherein the resin is structured by nano-imprint.
